(19) United States
(12) Patent Application Publication
(10) Pub. No.: US 2025/0076045 A1
(43) Pub. Date: Mar. 6, 2025

(54) LASER RECEIVER

(71) Applicant: Stanley Black & Decker Inc., New Britain, CT (US)

(72) Inventors: Dominic Maurice LEONE, Baltimore, MD (US); Fugen QIN, Lutherville-Timonium, MD (US); JB RING, Vienna, VA (US); Akash AGARWAL, Baltimore, MD (US); Michael C. SCHMITTDIEL, Baltimore, MD (US); MD Qumrul Hasan, Belcamp, MD (US)

(73) Assignee: Stanley Black & Decker Inc., New Britain, CT (US)

(21) Appl. No.: 18/806,099

(22) Filed: Aug. 15, 2024

Related U.S. Application Data
(60) Provisional application No. 63/536,579, filed on Sep. 5, 2023.

(51) Int. Cl. G01C 15/00; H01L 27/144

(52) U.S. Cl. CPC G01C 15/006; H10F 39/103

(57) ABSTRACT

A laser detector includes a detection section, the detection section includes an array of photo-detectors configured to detect a vertical position of a beam. The laser detector also includes an indication section, the indication section includes an array of illumination elements configured to indicate the vertical position of the laser beam. The detection section has a height H1. The indication section has a height H2. H2 is in a range of from 0.75 to 1.25 H1.

### CROSS-REFERENCE TO RELATED APPLICATIONS

This application claims benefit of Provisional Patent Application No. 63/536,579 filed Sep. 5, 2023. The entire contents of which are incorporated herein by reference.

### FIELD OF THE INVENTION

The present application relates to a laser receiver or detector for a construction tool such as a construction laser level.

### BACKGROUND

A laser level used in construction may project a laser beam. For example, a rotary laser level may project a laser beam and rotate the laser beam about an angle, such as 360 degrees. At significant distances from the laser level it may be difficult for a user to see the laser, and a user may desire to detect a location of the laser beam. Accordingly, a user may use a laser receiver, which may also be referred to as a laser detector. The laser receiver may detect the presence of a laser beam and provide an indication to a user.

### SUMMARY

According to an aspect of an example embodiment, a laser detector, includes: a detection section, the detection section comprising an array of photo-detectors configured to detect a vertical position of a laser beam; an indication section, the indication section comprising an array of illumination elements configured to indicate the vertical position of the laser beam; wherein the detection section has a height H1; wherein the indication section has a height H2; wherein H2 is in a range of from 0.75 to 1.25 times H1.

H2 may be in a range of from 0.8 to 1.2 times H1.

H2 may be in a range of from 0.8 to 1.1 times H1.

H2 may be in a range of from 0.9 to 1.1 times H1.

The indication section may be adjacent to the detection section.

The photo-detectors may comprise photo-diodes.

The illumination elements may comprise LEDs.

There may be at least 20 illumination elements.

There may be at least 20 photo-detectors.

The detection section may be spaced apart from the indication section by a distance W; and W may be 40 mm or less.

W may be 30 mm or less.

W may be 20 mm or less.

W may be 10 mm or less.

H2 may be at least 80 mm.

According to an aspect of an example embodiment, a laser detector, includes: a detection section, the detection section comprising an array of photo-detectors configured to detect a vertical position of a laser beam; an indication section, the indication section comprising an array of illumination elements configured to indicate the vertical position of the laser beam. The detection section has a height H1. The indication section has a height H2. H2 is in a range of from 0.75 to 1.25 times H1;

H2 may be at least 80 mm.

The detection section may be spaced apart from the indication section by a distance W; and W may be 40 mm or less.

There may be at least 20 illumination elements.

There may be at least 20 photo-detectors.

The illumination elements may comprise LEDs.

According to an aspect of an example embodiment, a laser detector includes: a detection section, the detection section comprising an array of photo-detectors configured to detect a vertical position of a laser beam; an indication section, the indication section comprising an array of illumination elements configured to indicate the vertical position of the laser beam; wherein the indication section is adjacent to the detection section; wherein the detection section has a height H1; wherein the indication section has a height H2; wherein H2 is in a range of from 0.8 to 1.2 times H1; wherein H2 is at least 80 mm.

There may be at least 25 illumination elements.

There may be at least 25 photo-detectors.

### BRIEF DESCRIPTION OF THE DRAWINGS

FIG. 1 is a side view of a rotary laser level according to an example embodiment;

FIG. 2 is a perspective view of a cross-line laser level according to an example embodiment;

FIG. 3 is a front view of a laser detector according to an example embodiment;

FIG. 4 is a front view of a laser detector according to an example embodiment;

FIG. 5 illustrates a rear view of a laser detector according to an example embodiment;

FIG. 6 is a front view of an exemplary embodiment of a circuit board and assembly for a laser detector according to an example embodiment; and

FIG. 7 is a schematic electronic diagram according to an example embodiment.

### DETAILED DESCRIPTION OF EXEMPLARY EMBODIMENTS

The drawings are for the purpose of illustration and description only and are not intended as a definition of the limits of the invention. In addition, it should be appreciated that structural features shown or described in any one embodiment herein can be used in other embodiments as well. As used in the specification and in the claims, the singular form of “a”, “an”, and “the” include plural referents unless the context clearly dictates otherwise.

All closed-ended (e.g., between A and B) and open-ended (greater than C) ranges of values disclosed herein explicitly include all ranges that fall within or nest within such ranges. For example, a disclosed range of 1-10 is understood as also disclosing, among other ranged, 2-10, 1-9, 3-9, etc.

As used herein, the terminology “at least one of A, B and C” and “at least one of A, B or C” each mean any one of A, B or C or any combination of A, B and C. For example, at least one of A, B and C may include only A, only B, only C, A and B, A and C, B and C, or A, B and C.

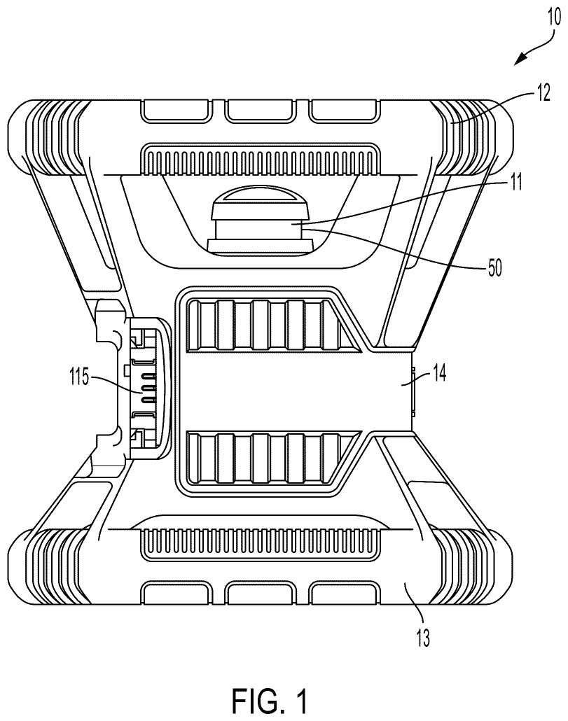

FIG. 1 illustrates a perspective view of a non-limiting, exemplary embodiment of a rotary laser level 10. The rotary laser level 10 includes a projector 11 which projects a laser beam 50. The laser beam 50 can be projected about an angle, such as 360 degrees along a horizontal plane. In some instances, the laser beam 50 can be projected about a smaller scanning angle rather than 360 degrees. Also, the level of the beam 50 may be changed. As shown, the rotary laser level includes a base housing 14. The base housing 14 may and a battery receiving portion 15. The battery receiving portion 15 of the example embodiment receives a removable battery pack for providing power to at least some parts of the rotary laser level 10, such as one or more motors and one or more laser generator such as a laser diode. The removable battery pack may be a power tool battery pack that is configured to selectively power one or more power tools such as a drill, sander, or saw, in addition to the rotary laser level 10.

As shown, the rotary laser level 10 includes an upper protective structure 12 and a lower protective structure 13. The rotary laser level 10 is shown in an upright position 10 in FIG. 1. In the upright position, the upper protective structure 12 is above the projector 11 and the lower protective structure 13 is at a bottom end. When in the upright position, the rotary laser level 10 may project laser beam 50 in a horizontal plane or at a specified angle relative to a horizontal plane. In the example embodiment, the rotary laser level 10 may be placed on its side and project the laser beam 50 along a vertical plane or at a specified angle relative to the vertical plane.

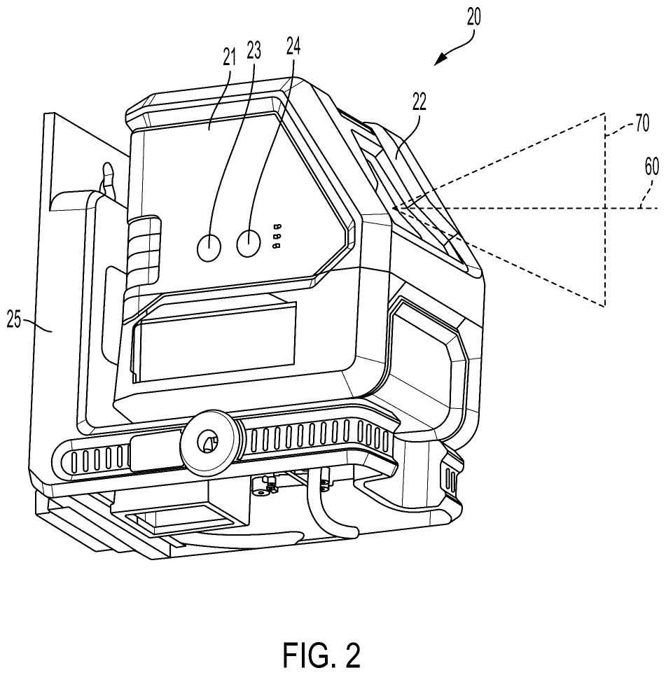

FIG. 2 illustrates an example embodiment of a cross-line laser level 20. The cross-line laser level 20 is rotatably mounted on bracket 25. The cross-line laser level 20 includes a housing 21. One or more laser generator may be in the housing 21. The one or more laser generator may be on a leveling assembly, such as a pendulum that is passively leveled by gravity. In other embodiments, the leveling assembly may be an active leveling assembly in which sensors are used to detect an orientation and motors are utilized to perform a leveling operation on the leveling assembly. The cross-line laser level 20 is configured to project a first laser line and a second laser line which intersects the first laser line. When placed in an upright orientation with a horizontal support such as a flat horizontal surface, the cross-line laser level 20 may project a horizontal line 60 and a vertical line 70. The cross-line laser level 20 may include various buttons 23, 24 for performing operations of the laser level 20. For example, the button 23 may individually activate and deactivate projection of the horizontal line 60 and button 24 may individually activate and activate projection of the vertical line 70. Accordingly, the cross-line laser level 20 may project either one or both of the horizontal line 60 and the vertical line 70 at a given time.

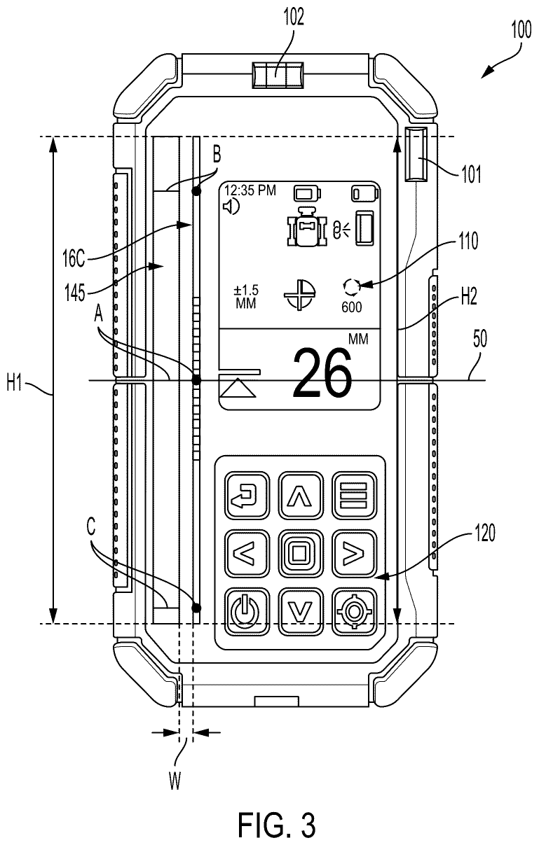

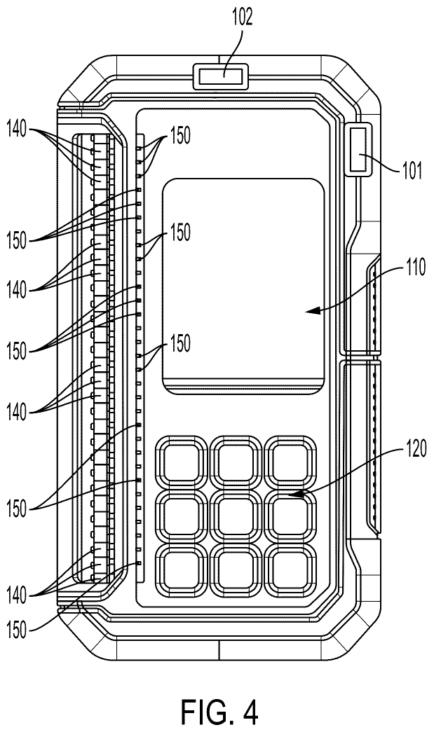

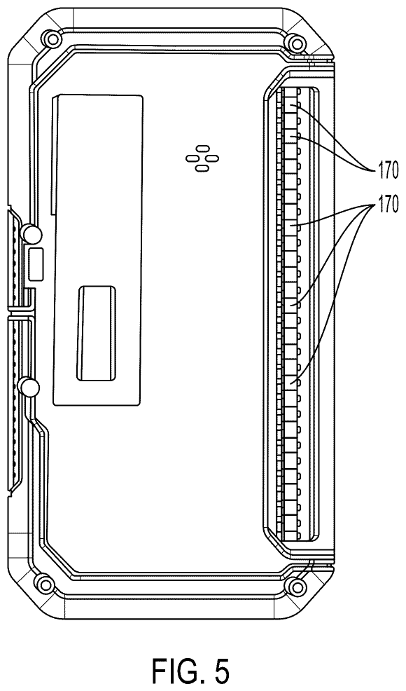

FIGS. 3-5 illustrate view of an example embodiment of a laser detector 100. FIG. 3 is a front view of the laser detector 100. FIG. 4 is a front view of the laser detector 100 with parts partially removed. FIG. 5 is a rear view of the laser detector 100.

The laser detector 100 includes a first bubble level 101 and a second bubble level 102. The bubble levels 101 and 102 assist a user in positioning the laser detector 100. For example, a user may utilize the bubble levels 101 and 102 to position the laser detector 100 square with a top surface along a horizontal plane. As shown in FIGS. 3 and 4, the laser detector 100 includes a screen 110 and a key pad 120 with a variety of input keys. The screen 110 can display various information regarding a laser level that the detector 100 is being used with, as well as information about the laser detector 100 itself. As shown in FIG. 3, the laser detector includes a window 130. The window 130 may be transparent or translucent. FIG. 4 illustrates the laser detector 100 with the window 130 and part of the laser detector housing removed. As shown in FIG. 4, there is a row of photo-detectors 140 aligned at a position behind the window 130. The photo-detectors 140 are arranged in a vertical row. In an example embodiment, the photo-detectors 140 may be photo-diodes. The photo-detectors 140 provide a detection section 145 with a height H1. The detection section 145 may be the same as or generally correspond to the height of window 130. A vertical row of light emitting diodes (LEDs) 150 are arranged next to the window 130 and photo-detectors 140. The LEDs 150 provide an indication section 160 with a height H2.

The height H2 may be at least 80 mm; at least 85 mm; at least 90 mm; at least 95 mm; at least 100 mm; or at least 110 mm.

The laser detector 100 may be used with any of a variety of different types of laser levels, such as the example embodiment of a rotary laser level 10 an the example embodiment of a cross-line laser level 20. In an example embodiment, in operation the laser detector 100 may be associated with laser level 10. The laser detector 100 may be placed at some distance away from the laser level 10. The laser detector 100 may be, for example, manually held by a user, magnetically attached to a metal structure or attached to a grade rod. Laser beam 50 may project onto the laser detector 100. In particular, laser beam 50 may project onto window 130 at a particular vertical elevation. One or more photo-detectors 140 behind the window detect the laser beam 50. The photo-detectors 140 are connected to a controller and the controller determines a vertical location of the laser beam 50 based on signals from the photo-detectors 140. Then, one or more LED 150 may be illuminated to indicate a vertical position of the laser beam 50.

For example, in the example embodiment, the laser beam 50 may project onto the laser detector 100 at a position A on the window 130, be detected by one or more photo-detectors 140 positioned at or near the position A, and then one or more LEDs 150 positioned at or near vertical position A may be illuminated to provide an indication of the vertical position of the laser beam 50. Similarly, the laser beam 50 may project onto the laser detector 100 at a higher vertical location B, be detected by one or more photo-detectors 140 positioned at or near the position B, and one or more LEDs 150 positioned at or near vertical position B may be illuminated to provide an indication of the vertical position of the laser beam 50 at B. The laser beam 50 may project onto the laser detector 100 at a lower vertical location c, be detected by one or more photo-detectors 140 positioned at or near the position C, and one or more LEDs 150 positioned at or near vertical position C may be illuminated to provide an indication of the vertical position of the laser beam 50 at C.

The laser detector 100 may be used similarly with the cross-line laser level 20. For example, the laser detector 100 may indicate a vertical position of horizontal line 60 projected by cross-line laser level 20.

In the example embodiment, the indication section 160 may have generally the same or a similar height to that of the detection section 145. Accordingly, in the example embodiment, the indication section 160 is configured to be sized so that it can display locations generally corresponding to where the laser beam 50 is detected. That is, if a laser beam 50 is detected at a position along the detection section 145, there is a corresponding position on the indication section 160 to indicate the detected position. In example embodiments, the height H2 of the indication section 160 is in a range of between 0.7 and 1.3 times the height H1 of the detection section 130; the height H2 of the indication section 160 is in a range of between 0.75 and 1.25 times the height H1 of the detection section 130; the height H2 of the indication section 160 is in a range of between 0.8 and 1.2 times the height H1 of the detection section 130; the height H2 of the indication section 160 is in a range of between 0.8 and 1.1 times the height H1 of the detection section 130; the height H2 of the indication section 160 is in a range of between 0.9 and 1.1 times the height H1 of the detection section 130.

In order to indicate a vertical height of the laser beam 50, the indication section 160 may illuminate one illumination member, such as one LED 150. In other embodiments, the indication section 160 may illuminate more than one illumination member, such as multiple LEDs 150. For example, the illumination section 150 may illuminate three LEDs 150. The middle LED 150 of the three illuminated LEDs may be the closest to the detected position. One or more LED 150 may be illuminated more brightly than the other LEDs 150. For example, in an embodiment, the center LED 150 of three illuminated LEDs 150 may be illuminated more brightly than the other two illuminated LEDs. In other example embodiments, other numbers of LEDs 150 may be illuminated, such as two LEDs 150 or four or more LEDs 150.

As shown in the example embodiment of FIG. 3, the LEDs 150 are adjacent to the photo-detectors 140 and so the detection section 145 is adjacent to the indication section 160. This may allow a user easy visualization. Also, it allows for the indication to be commensurate with the detection as they are adjacent. In the example embodiment, for example, the display 110 and the keypad 120 are not between the detection section 145 is adjacent to the indication section 160. As shown in FIG. 3, the detection section 145 and the indication section 160 are separated by a distance W. The distance W may be 40 millimeters (mm) or less; 30 mm or less; 20 mm or less; or 10 mm or less.

As shown in the example embodiment in FIG. 4, there are thirty-one (31) LEDs 150. The relatively large number of LEDs 150 allow for a precise location of the laser beam 50 to be displayed. That is, in the example embodiment, since there are thirty-one LEDs 150, at least thirty-one different vertical positions for the laser beam 50 may be displayed and the distance between the LEDs 150 is relatively small. In various example embodiments, there may be at least 10 LEDs 150 and the indication section may be configured to display at least 10 vertical locations; there may be at least 15 LEDs 150 and the indication section may be configured to display at least 15 vertical locations; there may be at least 20 LEDs 150 and the indication section may be configured to display at least 20 vertical locations; there may be at least 22 LEDs 150 and the indication section may be configured to display at least 22 vertical locations; there may be at least 25 LEDs 150 and the indication section may be configured to display at least 25 vertical locations.

In the example embodiment, there are twenty-nine (29) photo detectors 140. This allows for a precise determination of the location of the laser beam 50. In example embodiments, there may be at least 10 Photo-detectors 140 and the indication section may be configured to detect at least 10 vertical locations; there may be at least 15 Photo-detectors 140 and the indication section may be configured to detect at least 15 vertical locations; there may be at least 20 Photo-detectors 140 and the indication section may be configured to detect at least 20 vertical locations; there may be at least 22 Photo-detectors 140 and the indication section may be configured to detect at least 22 vertical locations; there may be at least 25 Photo-detectors 140 and the indication section may be configured to detect at least 25 vertical locations.

FIG. 5 illustrates a rear of the laser detector 100. As shown there may be a second row of photo detectors 170 at a rear of the laser detector 100. The photo detectors 170 may detect a laser beam 50 on a rear of the laser detector 100. In an embodiment, a laser beam 50 detected on the rear by the photo detectors 170 may be displayed by the indication section 160 and/or there may be an additional indication section on the rear of the laser detector 100. Though not shown, the example embodiment may include a window over the photo-detectors 170.

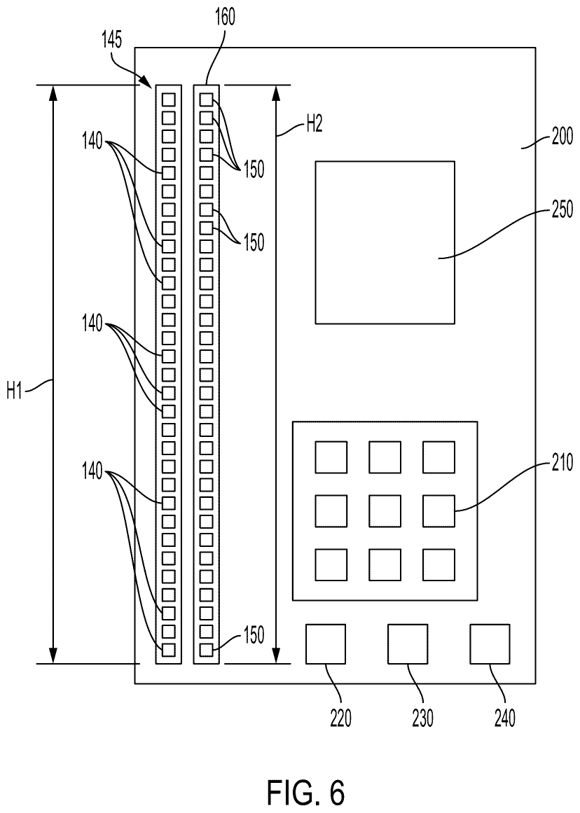

FIG. 6 illustrates a circuit board 200 that is mounted in the housing of the laser detector 100. The LEDs 150 and photo-detectors 140 are mounted on the circuit board 200. Additionally, as shown, switches 210 for the keypad 120 are mounted on the circuit board 200, as are a controller 220 and a wireless transceiver 230. The controller may include a microprocessor. Other electronic components may be mounted on the circuit board 200, such as various other sensors, such as an accelerometer. A speaker 240 may be mounted on the circuit board 200. In an embodiment, the user may depress a button on the laser level 10, 20 and the speaker 240 may make a sound, such as a beeping sound to allow a user to find the laser detector 100.

A display screen 250 for the display 110 may be mounted on the circuit board 200. Various information from a laser level 10, 20 or from the laser detector 100 may be displayed on the display screen 250. For example, a speed of rotation of a rotary laser level 10 may be displayed on the display screen 250. A battery state-of-charge for the laser detector 100 may be displayed on the display screen 250. The laser detector 100 may communicate to the laser level 10, 20 through the wireless transceiver 230.

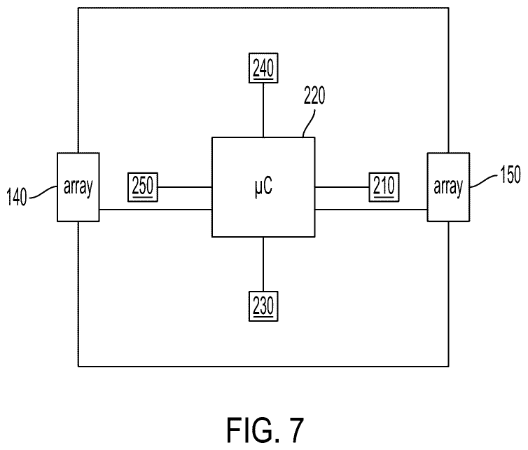

FIG. 7 is a schematic circuit diagram for the laser detector 100.

The laser detector 100 may also serve as a remote for the rotary laser level 10 or the cross-line laser level 20. In an example embodiment in which the laser detector 100 serves as a remote control for the rotary laser level 10, the laser detector may provide for one or more of on/off control of the rotary laser level; a speed of rotation of the laser; a slope angle of the laser level; height adjustment of the laser level; or a scan angle.

Although described by way of exemplary embodiments, it is understood that the words which have been used herein are words of description, rather than words of limitation. Although the description provided above provides detail for the purpose of illustration based on what is currently considered to be the most practical and preferred embodiments, it is to be understood that such detail is solely for that purpose and that the disclosure is not limited to the expressly disclosed embodiments, but, on the contrary, is intended to cover modifications and equivalent arrangements that are within the spirit and scope of the appended claims

It is to be understood that the present disclosure contemplates that, to the extent possible, one or more features of any embodiment can be combined or exchanged with one or more features of any other embodiment.

What is claimed is:

1. A laser detector, comprising:
a detection section, the detection section comprising an array of photo-detectors configured to detect a vertical position of a laser beam;
an indication section, the indication section comprising an array of illumination elements configured to indicate the vertical position of the laser beam;
wherein the detection section has a height H1;
wherein the indication section has a height H2;
wherein H2 is in a range of from 0.75 to 1.25 times H1.

2. The laser detector of claim 1, wherein H2 is in a range of from 0.8 to 1.2 times H1.

3. The laser detector of claim 1, wherein H2 is in a range of from 0.8 to 1.1 times H1.

4. The laser detector of claim 1, wherein H2 is in a range of from 0.9 to 1.1 times H1.

5. The laser detector of claim 1, wherein the indication section is adjacent to the detection section.

6. The laser detector of claim 1, wherein the photo-detectors comprise photo-diodes.

7. The laser detector of claim 1, wherein the illumination elements comprise LEDs.

8. The laser detector of claim 1, wherein there are at least 20 illumination elements.

9. The laser detector of claim 1, wherein there are at least 20 photo-detectors.

10. The laser detector of claim 1, wherein the detection section is spaced apart from the indication section by a distance W; and
wherein W is 40 mm or less.

11. The laser detector of claim 1, wherein W is 30 mm or less.

12. The laser detector of claim 1, wherein W is 20 mm or less.

13. The laser detector of claim 1, wherein W is 10 mm or less.

14. The laser detector of claim 1, wherein H2 is at least 80 mm.

15. A laser detector, comprising:
a detection section, the detection section comprising an array of photo-detectors configured to detect a vertical position of a laser beam;
an indication section, the indication section comprising an array of illumination elements configured to indicate the vertical position of the laser beam;
wherein the detection section has a height H1;
wherein the indication section has a height H2;
wherein H2 is in a range of from 0.75 to 1.25 times H1;
wherein H2 is at least 80 mm;
wherein the detection section is spaced apart from the indication section by a distance W; and
wherein W is 40 mm or less.

16. The laser detector of claim 15, wherein there are at least 20 illumination elements.

17. The laser detector of claim 16, wherein there are at least 20 photo-detectors.

18. The laser detector of claim 15, wherein the illumination elements comprise LEDs.

19. A laser detector, comprising:
a detection section, the detection section comprising an array of photo-detectors configured to detect a vertical position of a laser beam;
an indication section, the indication section comprising an array of illumination elements configured to indicate the vertical position of the laser beam;
wherein the indication section is adjacent to the detection section;
wherein the detection section has a height H1;
wherein the indication section has a height H2;
wherein H2 is in a range of from 0.8 to 1.2 times H1;
wherein H2 is at least 80 mm; and
wherein there are at least 25 illumination elements.

20. The laser detector of claim 19, wherein there are at least 25 photo-detectors.
